(19) United States
(12) Patent Application Publication
(10) Pub. No.: US 2026/0144056 A1
(43) Pub. Date: May 21, 2026

(54) SEMICONDUCTOR PACKAGE

(71) Applicant: Samsung Electronics Co., Ltd., Suwon-si (KR)

(72) Inventor: Young-Ja Kim, Suwon-si (KR)

(21) Appl. No.: 19/378,992

(22) Filed: Nov. 4, 2025

(30) Foreign Application Priority Data
Nov. 18, 2024 (KR) 10-2024-0164486

(51) Int. Cl. H01L 23/36; H01L 23/00; H01L 23/31; H01L 23/49; H01L 23/498; H01L 23/538; H01L 25/065

(52) U.S. Cl. CPC H10W 40/10; H10W 70/614; H10W 70/65; H10W 72/50; H10W 74/117; H10W 90/00; H10W 90/701; H10W 72/965; H10W 72/967; H10W 90/732

(57) ABSTRACT

A semiconductor package includes a base substrate, a first chip on the base substrate, a second chip on the first chip, a molding film extending around the first chip and the second chip, a redistribution layer on an upper surface of the molding film, and a plurality of outer posts that are on side surfaces of at least one of the first chip or the second chip, are electrically connected to the base substrate and the redistribution layer, and extend into the molding film, where the first chip or the second chip includes: a signal pad through which one or more electrical signals are transmitted, and a thermal pad configured to dissipate heat away from the semiconductor package, and where the plurality of outer posts include a signal post electrically connected to the signal pad or a thermal post electrically connected to the thermal pad.

### CROSS-REFERENCE TO RELATED APPLICATIONS

This application claims the benefit of Korean Patent Application No. 10-2024-0164486, filed on Nov. 18, 2024, in the Korean Intellectual Property Office, the disclosure of which is incorporated herein by reference in its entirety.

### TECHNICAL FIELD

The present disclosure relates to a semiconductor package.

### BACKGROUND

With the development of the electronics industry, a demand for high functionalization, high speed, and miniaturization of an electronic component is increasing. Accordingly, a method of stacking and mounting multiple semiconductor chips on one package wiring structure or a method of stacking a package on another package may be used.

Recently, a semiconductor package may be highly integrated and may have desirable performance characteristics. Accordingly, the thermal stability of and securing sufficient signal lines of a semiconductor package including multiple semiconductor chips may be desirable.

### SUMMARY

An aspect provides a semiconductor package in which multiple signal lines may be secured through a wide area and in which a thermal property is improved.

However, the goals to be achieved by example embodiments of the present disclosure are not limited to the objectives described above and other objects may be clearly understood from the following example embodiments by those skilled in the art.

According to an aspect, there is provided a semiconductor package including a base substrate, a first chip on the base substrate, a second chip on the first chip, a molding film extending around the first chip and the second chip, a redistribution layer on an upper surface of the molding film, and a plurality of outer posts that are on side surfaces of at least one of the first chip or the second chip, are electrically connected to the base substrate and the redistribution layer, and extend into the molding film, where the first chip or the second chip includes: a signal pad through which one or more electrical signals are transmitted, and a thermal pad configured to dissipate heat away from the semiconductor package, and where the plurality of outer posts include a signal post electrically connected to the signal pad or a thermal post electrically connected to the thermal pad.

According to another aspect, there is also provided a semiconductor package including a base substrate, a first chip group including a plurality of first chips on the base substrate, a first molding film extending around the first chip group, a first redistribution layer on the first molding film, a second chip group including a plurality of second chips on the first redistribution layer, and a plurality of first outer posts electrically connected to the base substrate and the first redistribution layer, and extending into the first molding film, where the plurality of first outer posts are free from overlap with the first chip group and the second chip group in a first direction perpendicular to an upper surface of the base substrate, and where at least one first outer post of the plurality of first outer posts is electrically connected to at least one second chip of the plurality of second chips through the first redistribution layer.

According to still another aspect, there is also provided a semiconductor package including a redistribution substrate, a plurality of chips that are on the redistribution substrate and are offset from each other in a first direction parallel to an upper surface of the redistribution substrate, a molding film extending around the plurality of chips, a redistribution layer on the molding film, and a plurality of outer posts that are on the redistribution substrate, electrically connected to the redistribution layer, and extend into the molding film, where the redistribution substrate includes: a first chip connection pad in a chip area facing the plurality of chips in a direction perpendicular to the upper surface of the redistribution substrate, and electrically connected to a signal pad of a first chip of the plurality of chips, a second chip connection pad in the chip area, and electrically connected to a thermal pad of the first chip, and a plurality of outer connection pads electrically connected to the first chip connection pad or the second chip connection pad, and where the plurality of outer posts are on the plurality of outer connection pads.

According to example embodiments, the present disclosure provides a semiconductor package in which multiple signal lines may be secured through a wide area and in which a thermal property is improved without increasing an entire thickness.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is an example cross-sectional diagram illustrating a semiconductor package according to some example embodiments of the present disclosure;

FIG. 2 is an example cross-sectional diagram illustrating a semiconductor package according some example embodiments of the present disclosure;

FIG. 3 is an enlarged diagram of part A of FIG. 1;

FIG. 4 is an example cross-sectional diagram illustrating a semiconductor package according to various example embodiments of the present disclosure;

FIG. 5 is an example cross-sectional diagram illustrating a semiconductor package according to various example embodiments of the present disclosure;

FIG. 6 is an example cross-sectional diagram illustrating a semiconductor package according to various example embodiments of the present disclosure;

FIG. 7 is an example cross-sectional diagram illustrating a semiconductor package according to various example embodiments of the present disclosure;

FIG. 8 is a cross-sectional diagram illustrating a second chip group that is aligned on or with a carrier according to example embodiments of the present disclosure;

FIG. 9 is a cross-sectional diagram illustrating a second molding film that surrounds or extends around a second chip group according to example embodiments of the present disclosure;

FIG. 10 is a cross-sectional diagram illustrating a redistribution layer that is formed on a second molding film according to example embodiments of the present disclosure;

FIG. 11 is a cross-sectional diagram illustrating a first chip group that is aligned on or with a redistribution layer, an outer post, and a connection post according to example embodiments of the present disclosure;

FIG. 12 is a cross-sectional diagram illustrating a first molding film that is formed on a redistribution layer according to example embodiments of the present disclosure;

FIG. 13 is a cross-sectional diagram illustrating a base substrate that is formed on a first molding film according to example embodiments of the present disclosure; and

FIG. 14 is a cross-sectional diagram illustrating a semiconductor package that is separated from a carrier according to example embodiments of the present disclosure.

### DETAILED DESCRIPTION

Before example embodiments are described, terms or words used in the present disclosure and the accompanying claims may not be limited to general definitions or dictionary definitions. Thus, since example embodiments described in the present disclosure and configurations illustrated in the accompanying drawings are merely example embodiments and do not represent the entirety of the present disclosure, it should be understood that various equivalents and modifications that may replace the example embodiments and configurations may be present at the time of filing the application of the present disclosure.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

Hereinafter, a semiconductor device according to example embodiments will be described with reference to the accompanying drawing.

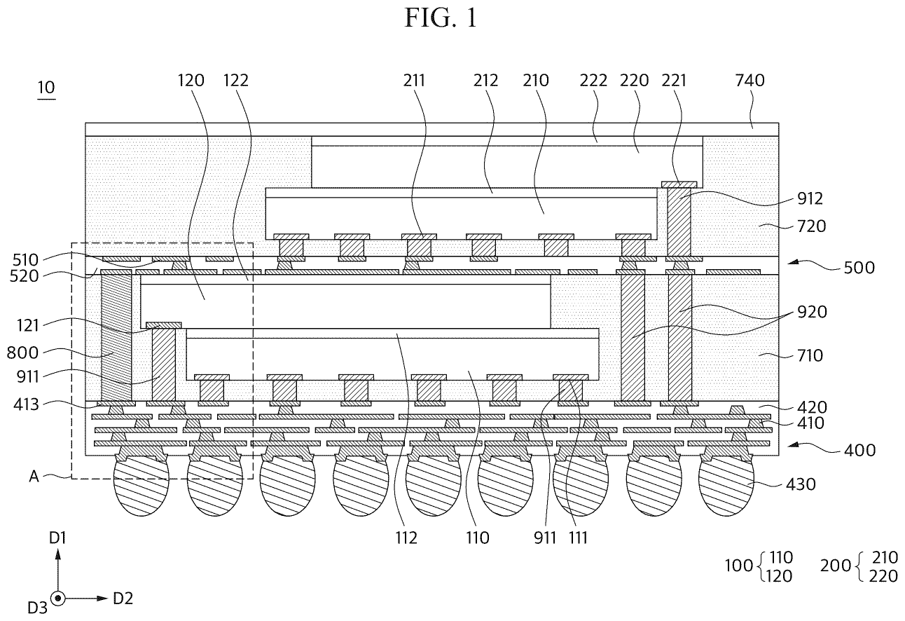

FIG. 1 is an example cross-sectional diagram illustrating a semiconductor package 10 according to some example embodiments.

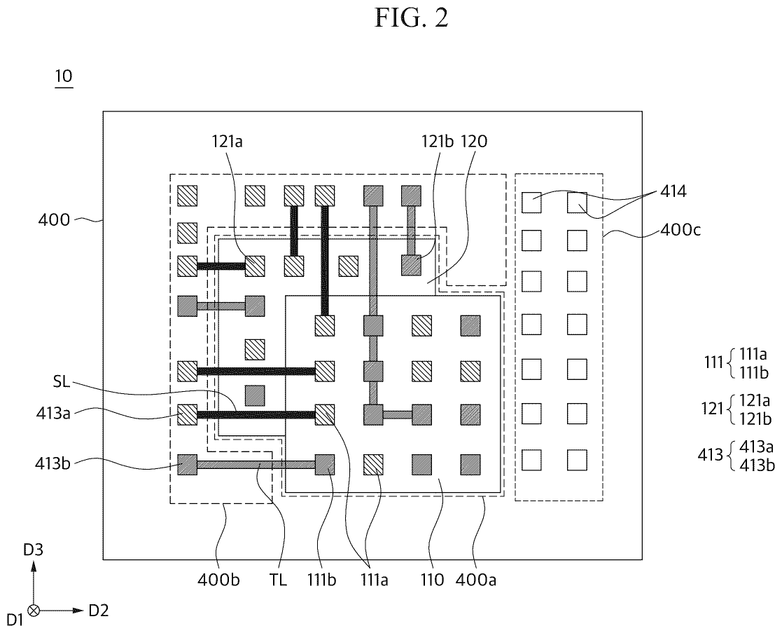

FIG. 2 is an example cross-sectional diagram illustrating the semiconductor package 10 according to some example embodiments.

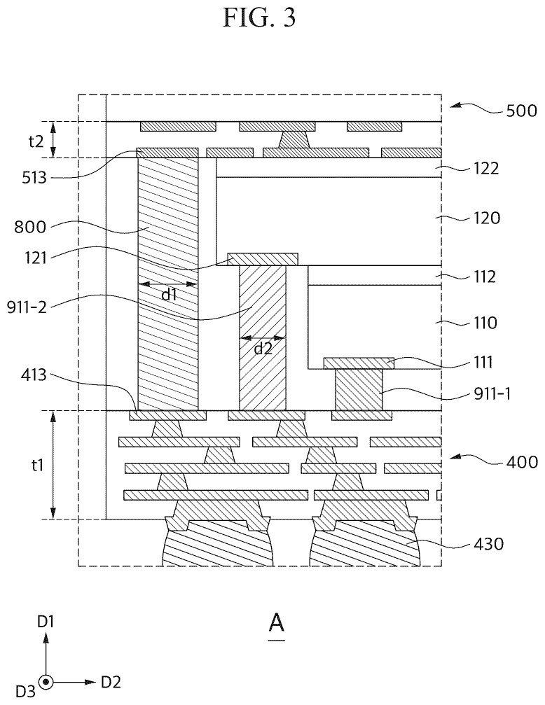

FIG. 3 is an enlarged diagram of part A of FIG. 1.

In some example embodiments, the semiconductor package 10 may include a base substrate 400, a first chip group 100 disposed above or on the base substrate 400, a first molding film 710 that surrounds or extends around the first chip group 100, and a redistribution layer 500 disposed on the first molding film 710.

In some example embodiments, the first chip group 100 may include at least one chip. For example, referring to FIGS. 1 through 3, the first chip group 100 may include a first chip 110 and a second chip 120 disposed above or on the base substrate 400. FIGS. 1 through 3 illustrate that the first chip group 100 includes two chips, but it is merely an example. For example, the first chip group 100 may include one chip or three or more chips.

In some example embodiments, at least one of a plurality of chips 110 and 120 included in the first chip group 100 may be a memory semiconductor chip. The memory semiconductor chip may be, for example, a volatile memory such as a dynamic random access memory (DRAM) or a static random access memory (SRAM). In some embodiments, the memory semiconductor chip may be a non-volatile memory such as a flash memory, a phase-change random access memory (PRAM), a magnetic random access memory (MRAM), a ferroelectric random access memory (FeRAM), or a resistive random access memory (RRAM).

In some example embodiments, at least one of the plurality of chips 110 and 120 included in the first chip group 100 may be a logic semiconductor chip. The logic semiconductor chip may be an application processor (AP) such as a central processing unit (CPU), a graphic processing unit (GPU), a field-programmable gate array (FPGA), a digital signal processor, an encryption processor, a microprocessor, a microcontroller, and an application-specific integrated circuit.

In some example embodiments, the plurality of chips 110 and 120 included in the first chip group 100 may be stacked to be offset from each other in a direction parallel to an upper surface (or a surface) of the base substrate 400. Here, being stacked to be offset from each other may be understood as being stacked to be staggered from each other. For example, referring to FIGS. 2 and 3, while the second chip 120 is stacked and disposed above the first chip 110, the second chip 120 may be disposed to be staggered from the first chip 110 in a second direction D2 or a third direction D3 parallel to the upper surface of the base substrate 400 so that a portion thereof overlaps the first chip 110 in a first direction D1 perpendicular to the upper surface of the base substrate 400 and another portion does not overlap in the first direction D1.

In the following description, the first direction D1 may be a direction perpendicular to the upper surface of the base substrate 400. The second direction D2 may be a direction parallel to the upper surface of the base substrate 400 and perpendicular to the first direction D1. The third direction D3 may be a direction perpendicular to both of the first direction D1 and the second direction D2.

In some example embodiments, the base substrate 400 to which the first chip group 100 is mounted or attached may be a wiring structure for a package. For example, the base substrate 400 may be a printed circuit board (PCB) or a ceramic substrate. In some embodiments, the base substrate 400 may be a wiring structure for a wafer level package (WLP) manufactured at a wafer level.

In some example embodiments, the base substrate 400 may be a glass substrate, a ceramic substrate, or a plastic substrate, but it is merely an example. For example, the base substrate 400 may include a resin (e.g., prepreg, Ajinomoto Build-up Film (ABF), FR-4, or bismaleimide triazine (BT)) impregnated together with an inorganic filler in a core material such as a glass fiber (e.g., a glass cloth or a glass fabric).

In some embodiments, the base substrate 400 may be formed as a redistribution layer produced by using a redistribution process. For example, the base substrate 400 may be a front redistribution layer (FRDL) of a fan-out package. In the following description, the base substrate 400 which is implemented as the redistributed layer may be referred to as a “redistribution substrate”.

In some example embodiments, the base substrate 400 formed as the redistribution layer may include a redistribution insulation film 420 and a redistribution structure 410.

In some example embodiments, the redistribution insulation film 420 may be formed of at least one material selected from a phenolic resin, an epoxy resin, or polyimide. The base substrate 400 may include at least one material selected from tetrafunctional epoxy, polyphenylene ether, epoxy/polyphenylene oxide, bismaleimide triazine (BT), Thermount, cyanate ester, or a liquid crystal polymer.

In some example embodiments, the redistribution insulation film 420 may include a photoimageable dielectric. As an example, the redistribution insulation film 420 may include a photosensitve polymer. The photosensitive polymer may be formed of, for example, at least one of photosensitive polyimide, polybenzoxazole, a phenolic polymer, or a benzocyclobutene-based polymer. As another example, the redistribution insulation film 420 may be formed of a silicon oxide film, a silicon nitride film, or a silicon oxynitride film.

According to some example embodiments, the redistribution insulation film 420 may include a plurality of insulation films stacked in the first direction D1. The plurality of insulation films may surround or extend around a wiring pattern and a wiring via of the redistribution structure 410.

Although not illustrated, a surface of the redistribution insulation film 420 may be covered with or overlapped by solder resist. For example, a passivation film may be formed on the surface of the redistribution insulation film 420. The passivation film formed on the surface of the redistribution insulation film 420 may protect the redistribution structure 410 and other structures from external impact or moisture. The passivation film may include the solder resist. However, the present disclosure is not limited thereto.

According to some example embodiments, the redistribution structure 410 may be disposed in the redistribution insulation film 420 and electrically connected to the first chip group 100. The redistribution structure 410 may include the wiring pattern and the wiring via that connects each wiring pattern. For example, the redistribution structure 410 may have a multilayer structure in which two or more wiring patterns or two or more wiring vias are stacked alternately. The wiring pattern may be a part for horizontal connection between conductive elements, and the wiring via may be a part for vertical connection between conductive elements. For example, the wiring pattern may extend in the second direction D2 or the third direction D3. The wiring via may connect wiring patterns spaced apart in the first direction D1.

In some example embodiments, the redistribution structure 410 may include a conductive material. For example, the redistribution structure 410 may include copper (Cu), aluminum (Al), silver (Ag), tin (Sn), gold (Au), nickel (Ni), lead (Pb), titanium (Ti), or an alloy thereof, but it is merely an example.

In some example embodiments, an external connection terminal 430 may be formed on a lower surface of the redistribution substrate 400. As an example, the external connection terminal 430 may include a solder ball or a solder bump. As another example, the external connection terminal 430 may include a micro bump. The external connection terminal 430 may have a spherical shape or an oval shape, but it is merely an example. The number of external connection terminals 430, an interval between the external connection terminals 430, disposition or a shape of the external connection terminal 430, or the like is not limited to the examples described herein and may vary depending on a design. The external connection terminal 430 may include, for example, tin (Sn), indium (In), bismuth (Bi), antimony (Sb), copper (Cu), silver (Ag), zinc (Zn), lead (Pb), and a combination thereof, but it is merely an example.

In some example embodiments, the external connection terminal 430 may electrically connect the redistribution structure 410 to an external device. Accordingly, the external connection terminal 430 may provide an electrical signal to the redistribution structure 410 or provide, to the external device, an electrical signal provided from the redistribution structure 410.

In some example embodiments, the plurality of chips 110 and 120 included in the first chip group 100 may be disposed so that surfaces on which chip pads 111 and 121 are disposed to face the base substrate 400. For example, referring to FIG. 1, the first chip 110 and the second chip 120 may be electrically connected to the base substrate 400 when the surfaces on which the chip pads 111 and 121 are formed are disposed to face the base substrate 400.

In some example embodiments, each chip included in the first chip group 100 may include a plurality of chip pads. For example, the first chip 110 may include a plurality of first chip pads 111. For example, the second chip 120 may include a plurality of second chip pads 121.

In some example embodiments, a plurality of chip pads 111 and 121 may include a signal pad used to transmit a signal to an outside (e.g., externally) and a thermal pad used to transfer heat generated in a chip to the outside. For example, and referring to FIG. 2, the first chip pads 111 may include a plurality of first signal pads 111a and a plurality of first thermal pads 111b, and the second chip pads 121 may include a plurality of second signal pads 121a and a plurality of second thermal pads 121b.

In some example embodiments, the plurality of chips 110 and 120 may include various chip circuits, such as a signal processing circuit, a signal amplification circuit, a data transmission/reception circuit, a data input/output circuit, a data memory circuit, and/or a power supply circuit. Signal pads 111a and 121a may be electrically connected to a chip circuit and used to input an electrical signal to the chip circuit or output an electrical signal from the chip circuit.

In some example embodiments, a plurality of signal pads of one chip may be electrically separated or isolated from each other. In other words, each signal pad may independently transmit or receive a signal.

In some example embodiments, thermal pads 111b and 121b are distinguished from the signal pads 111a and 121a and may be electrically insulated (e.g., electrically isolated or separated) from the signal pads 111a and 121a. The thermal pads 111b and 121b of the chips 110 and 120 may be used to emit or dissipate heat generated in or by the chips 110 and 120 to an outside of the chips 110 and 120 (e.g., away from the semiconductor package 10).

In some example embodiments, the thermal pads 111b and 121b may be electrically insulated from a circuit that performs data processing such as an input and output of data, calculation of data, or storing data in the chip circuit. That is, the thermal pads 111b and 121b may receive heat energy generated by the circuit performing the data processing in the chips 110 and 120, but may be in a floating state of being electrically insulated (e.g., electrically isolated or separated) from the circuit.

In some example embodiments, some thermal pads of a plurality of thermal pads of one chip may be electrically connected to each other. That is, two or more thermal pads 111b and 121b disposed at different positions may be electrically connected to each other. Particularly, a plurality of thermal pads 111b and 121b connected to each other in an area that may be desirable for heat emission or dissipation in the chips 110 and 120 may be disposed, so that heat emission or dissipation efficiency may be increased and a thermal property of a chip may be improved.

In some example embodiments, as the chip pads 111 and 121 and a plurality of wiring posts 911 connected to the base substrate 400 are electrically connected to each other, the plurality of chips 110 and 120 included in the first chip group 100 may be electrically connected to the base substrate 400. For example, each of a first signal pad 111a and a first thermal pad 111b of the first chip 110 may be electrically connected to the base substrate 400 through wiring posts 911-1, and each of a second signal pad 121a and a second thermal pad 121b of the second chip 120 may be electrically connected to the base substrate 400 through wiring posts 911-2. Accordingly, some of the wiring posts 911 connected to the first signal pad 111a and the second signal pad 121a may function as signal transmission paths, and other wiring posts 911 connected to the first thermal pad 111b and the second thermal pad 121b may function as heat transfer paths.

In some example embodiments, when the first chip 110 and the second chip 120 are stacked to be offset from each other, a second chip pad 121 of the second chip 120 may be disposed on a surface of the second chip 120, which does not overlap (e.g., is free from overlap with) the first chip 110 in the first direction D1. For example, referring to FIGS. 1 and 2 together, the second chip 120 may be disposed at an upper side of the first chip 110 to be offset in both of the second direction D2 and the third direction D3, and the plurality of second chip pads 121 may be disposed on a surface of the second chip 120, which is at least partially exposed beyond an edge of the first chip 110.

In some example embodiments, a surface of the first chip 110 that faces the base substrate 400 (e.g., a lower surface of the first chip 110) may not have a portion covered with or overlapped by another chip. In this case, a first chip pad 111 may be disposed throughout an entire area of a surface of the first chip 110 that faces the base substrate 400. For example, referring to FIGS. 1 and 2 together, multiple first chip pads 111 may be disposed in a plurality of rows and columns throughout the entire area of the surface of the first chip 110 that which faces the base substrate 400. As such, since chip pads may be disposed throughout the entire area of the surface of the first chip 110 that faces the base substrate 400, the first chip 110 may have more chip pads than the second chip 120.

In some example embodiments, since the first chip 110 may include the chip pads which are distributed evenly in the entire area of the surface facing the base substrate 400, the number of signal pads and thermal pads and an area in which the signal pads and the thermal pads are distributed may be sufficiently secured in the first chip group 110. Accordingly, a chip group having multiple signal transmission paths and excellent or desirable heat performance may be implemented.

In some example embodiments, the first molding film 710 may be disposed to surround or extend around the first chip group 100 at an upper side of the base substrate 400. The first molding film 710 may include an insulation material. For example, the first molding film 710 may include an insulating polymer material such as an epoxy molding compound (EMC). In some embodiments, the first molding film 710 may include a thermosetting resin such as an epoxy resin or a thermoplastic resin such as polyimide.

In some example embodiments, the redistribution layer 500 may be disposed on the first molding film 710. The redistribution layer 500 may be formed by using a redistribution process.

In some example embodiments, the redistribution layer 500 may have a structure similar to that of the above-described redistribution substrate. In other words, the redistribution layer 500 may include a redistribution insulation film 520 and a redistribution structure 510. A description of the redistribution substrate may be referenced for detailed descriptions of the redistribution insulation film 520 and the redistribution structure 510.

In some example embodiments, an adhesive member may be interposed between the first chip 110 and the second chip 120 and between the second chip 120 and the redistribution layer 500. For example, referring to FIG. 1, a first adhesive member 112 may be disposed on an upper surface of the first chip 110, and the first chip 110 may be fixed or attached to the second chip 120 through the first adhesive member 112. A second adhesive member 122 may be disposed on an upper surface of the second chip 120, and the second chip 120 may be fixed or attached to the redistribution layer 500 through the second adhesive member 122.

In some example embodiments, the first adhesive member 112 and the second adhesive member 122 may be an adhesive film. The adhesive film may be, for example, a die attach film. The die attach film may be an inorganic adhesive or a polymeric adhesive.

In some example embodiments, a second chip group 200 including a plurality of chips may be disposed above or on the redistribution layer 500. For example, referring to FIG. 1, the second chip group 200 may include a third chip 210 and a fourth chip 220 disposed above or on the redistribution layer 500. FIG. 1 illustrates that the first chip group 200 includes two chips, but it is merely an example. For example, the second chip group 200 may include only one chip or three or more chips.

In some example embodiments, a plurality of chips 210 and 220 included in the second chip group 200 may be disposed so that surfaces on which chip pads 211 and 221 are disposed face the base substrate 500. For example, referring to FIG. 1, the third chip 210 and the fourth chip 220 may be electrically connected to the base substrate 400 when the surfaces on which the chip pads 211 and 221 are formed are disposed to face the base substrate 400.

In some example embodiments, each chip included in the second chip group 200 may include a plurality of chip pads. For example, the third chip 210 may include a plurality of third chip pads 211. For example, the fourth chip 220 may include a plurality of fourth chip pads 221.

In some example embodiments, a plurality of chip pads 211 and 221 of the second chip group 200 may include a signal pad used to transmit a signal to an outside (e.g., externally) and a thermal pad used to transfer heat generated by a chip to the outside (e.g., away from the semiconductor package 10). For example, the third chip pads 211 may include a plurality of third signal pads and a plurality of third thermal pads. For example, the fourth chip pads 221 may include a plurality of fourth signal pads and a plurality of fourth thermal pads.

In some example embodiments, as the chip pads 211 and 221 and a wiring post 912 connected to the redistribution layer 500 are electrically connected to each other, the plurality of chips 210 and 220 included in the second chip group 200 may be electrically connected to the redistribution layer 500. For example, each of a third chip pad 211 of the third chip 210 and a fourth chip pad 221 of the fourth chip 220 may be electrically connected to the redistribution layer 500 through the wiring post 912.

In some example embodiments, similarly to the first chip group 100, the plurality of chip pads 211 and 221 of the second chip group 200 may include the signal pad used to transmit the signal to the outside and the thermal pad used to transfer the heat generated by a chip to the outside (e.g., away from the semiconductor package 10). Descriptions of the signal pad and the thermal pad of the first chip group 100 may be referenced for the signal pad and the thermal pad of the second chip group 200.

In some example embodiments, similarly to the first chip group 100, the plurality of chips 210 and 220 of the second chip group 200 may be stacked to be offset from each other in the second direction D2 and/or the third direction D3. A description of the first chip group 100 may be referenced for the offset configuration of the second chip group 200 and the number of chip pads according thereto.

Also, the description of the first chip group 100 may be referenced for types of the plurality of chips 210 and 220 forming the second chip group 200.

In addition, the third chip 210 of the second chip group 200 may be fixed or attached to the fourth chip 220 through a third adhesive member 212, and the fourth chip 220 may be fixed or attached to an uppermost insulation film through a fourth adhesive member 222. Descriptions of the first adhesive member 112 and the second adhesive member 122 may be referenced for descriptions of the third adhesive member 212 and the fourth adhesive member 222.

In some example embodiments, the second molding film 720 may be disposed to surround or extend around the second chip group 200 at an upper side of the redistribution layer 500. The second molding film 720 may include an insulation material. For example, the second molding film 720 may include an insulating polymer material such as an epoxy molding compound (EMC). In some embodiments, the second molding film 720 may include a thermosetting resin such as an epoxy resin or a thermoplastic resin such as polyimide.

In some example embodiments, the second molding film 720 may be formed of a material different from that of the first molding film 710. For example, both of the first molding film 710 and the second molding film 720 may include a filler, but a content of the filler of the first molding film 710 and a content of the filler of the second molding film 720 may be different from each other. A production cost or a manufacturing process of the semiconductor package 10 as well as performance of the semiconductor package 10 may be optimized or controlled by forming the first molding film 710 and the second molding film 720 with different materials according to performance or thermal properties of the first chip group 100 and the second chip group 200.

In some example embodiments, the semiconductor package 10 may include an outer post 800 outside of (or external to) the first chip group 100 or the second chip group 200. For example, referring to FIG. 1, the semiconductor package 10 may include the outer post 800 which is disposed at a side of the first chip 110 and the second chip 120.

In some example embodiments, the outer post 800 may penetrate or extend into the first molding film 710 to be electrically connected to each of the base substrate 400 and the redistribution layer 500. For example, referring to FIG. 1, the outer post 800 may extend from the upper surface of the base substrate 400 to the redistribution layer 500 in the first direction D1 and may be disposed to penetrate or extend into the first molding film 710. One end of the outer post 800 may be electrically connected to an outer connection pad 413 provided to the base substrate 400, and another end thereof may be electrically connected to an outer connection pad 513 (e.g., FIG. 3) provided to the redistribution layer 500. The outer connection pad 413 of the base substrate 400 may be electrically connected to the redistribution structure 410 of the base substrate 400, and the outer connection pad 513 of the redistribution layer 500 may be electrically connected to the redistribution structure 510 of the redistribution layer 500. Accordingly, the outer post 800 may be electrically connected to both of the redistribution structure 410 of the base substrate 400 and the redistribution structure 510 of the redistribution layer 500.

In some example embodiments, one or more outer posts 800 may be disposed at the side of the first chip 110 and the second chip 120. For example, referring to FIGS. 1 and 2, a plurality of outer connection pads 413 spaced apart from positions of the first chip 110 and the second chip 120 in a direction parallel to the second direction D2 may be disposed on the upper surface of the base substrate 400, and the outer post 800 may be disposed on the outer connection pads 413. Accordingly, a plurality of outer posts 800 may be disposed in at least one row or column at the side of the first chip 110 and the second chip 120.

In some example embodiments, the outer post 800 may be disposed to be spaced apart from the first chip group 100 and the second chip group 200 in the second direction D2 or the third direction D3.

For example, referring to FIG. 1, while disposed at a side of the first chip group 100 on the base substrate 400, the outer post 800 may be disposed at a position not overlapping (or free from overlap with) the second chip group 200 in the first direction D1. That is, the outer post 800 may be disposed at a position not overlapping (or free from overlap with) both of the first chip group 100 and the second chip group 200 in the first direction D1.

In some example embodiments, the plurality of outer posts 800 may be electrically connected to the first chip group 100 disposed above or on the base substrate 400. In addition, the plurality of outer posts 800 may be also electrically connected to the second chip group 200 disposed above or on the redistribution layer 500. For example, as being electrically connected to the first chip pads 111 of the first chip 110 and the second chip pads 121 of the second chip 120, the plurality of outer posts 800 may be electrically connected to the first chip 110 and the second chip 120.

Hereinafter, a connection relationship between the outer post 800 and a chip will be described in detail with reference to FIGS. 1 and 2 together. FIG. 2 is a cross-sectional diagram of the semiconductor package 10 which is viewed from the upper surface of the base substrate 400 in the first direction D1. The first chip 110, the second chip 120, the first chip pad 111, and the second chip pad 121, which are illustrated in FIG. 2, may be understood as being projected on the cross-sectional diagram. Also, since the wiring post 911 and a chip connection pad are connected to each chip pad, and since the outer post 800 is connected to each outer connection pad 413, a position of the wiring post 911 or the chip connection pad may be understood as corresponding to a position of a chip pad illustrated in FIG. 2, and a position of the outer post 800 may be understood as corresponding to a position of the outer connection pad 413.

Referring to FIGS. 1 and 2 together, the base substrate 400 may include the plurality of outer connection pads 413 to which the outer posts 800 are individually disposed. The plurality of outer connection pads 413 may include a first outer connection pad 413a electrically connected to each of the signal pads 111a and 121a of the first chip group 100 and a second outer connection pad 413b electrically connected to each of the thermal pads 111b and 121b of the first chip group 100. For example, as illustrated in FIG. 2, in some example embodiments, a signal connection line SL that electrically connects at least one of the signal pads 111a and 121a of the first chip group 100 and at least one of first outer connection pads 413a may be formed in the semiconductor package 10. In addition, in some example embodiments, a thermal connection line TL that electrically connects at least one of the thermal pads 111b and 121b of the first chip group 100 and at least one of second outer connection pads 413b may be formed in the semiconductor package 10. Here, the signal connection line SL and the thermal connection line TL may be formed through the redistribution structure 410 of the base substrate 400. However, in various example embodiments of the present disclosure, the signal connection line SL and the thermal connection line TL may be distinguished from the redistribution structure 410 of the base substrate 400 and formed separately at an inside or an outside of the base substrate 400.

In some example embodiments, the plurality of outer posts 800 may include a signal post disposed on the first outer connection pad 413a and a thermal post disposed on the second outer connection pad 413b. In other words, with respect to the plurality of outer posts 800, the signal post may be electrically connected to the signal pads 111a and 121a of chips to function as a signal transmission path of the chips. Also, with respect to the plurality of outer posts 800, the thermal post may be electrically connected to the thermal pads 111b and 121b of the chips to function as a heat emission path for heat generated in the chips.

In some example embodiments, the plurality of outer posts 800 may include a material configured to perform signal transmission and heat transfer, for example, a metal such as copper (Cu). However, a material of the outer post 800 may include, in addition to copper, any material configured to perform the functionality described herein and high thermal conductivity.

In some embodiments, the plurality of outer posts 800 may be electrically connected to the third chip 210 and the fourth chip 220 of the second chip group 200 through the redistribution layer 500. A connection relationship between the outer post 800 and the third chip 210 and the fourth chip 220 may be understood with reference to the above-described connection relationship between the outer post 800 and the first chip 110 and the second chip 120. For example, the redistribution layer 500 may include the outer connection pad 513 connected to the outer post 800 and a chip connection pad connected to a chip, and among the outer posts 800, the signal post may be connected to the signal pad of the third chip 210 or the signal pad of the fourth chip 220, and the thermal post may be connected to the thermal pad of the third chip 210 or the thermal pad of the fourth chip 220.

In some example embodiments, among the plurality of outer posts 800, a signal post electrically connected to the signal pads 111a and 121a of one of chips 110, 120, 210, and 220 may be electrically insulated (e.g., electrically isolated or separated) from a signal pad other than a signal pad to which the signal post is connected in the one of the chips. Thus, an electrical signal transmitted to and received from one signal post may not be transmitted to a signal pad other than a signal pad connected to the signal post.

In some example embodiments, the thermal post among the plurality of outer posts 800 may be electrically insulated (e.g., electrically isolated or separated) from the signal pads 111a and 121a of the chips 110, 120, 210, and 220. In other words, the thermal post which is electrically insulated from the thermal pads 111b and 121b of the chips among the plurality of outer post 800 may be electrically insulated from the signal pads 111a and 121a of the chips 110, 120, 210, and 220.

In some example embodiments, one thermal post among the plurality of outer posts 800 may be electrically connected to the plurality of thermal pads 111b and 121b.

In some example embodiments, the plurality of outer posts 800 may be electrically connected to signal pads and thermal pads of the first chip group 110 and/or the second chip group 200, so that a signal area may be expanded and the thermal properties thereof may be improved.

Particularly, as illustrated in FIG. 2, in the semiconductor package 10 according to the present disclosure, the outer post 800 may be disposed in an available space outside an area in which a plurality of chips are disposed, so that the signal area and the thermal properties may be improved while an entire thickness of the package is minimized or inhibited. That is, in the semiconductor package 10, the plurality of outer connection pads 413 and the outer posts 800 connected thereto may be disposed in an outer area 400b outside a chip area 400a that is the area in which the plurality of chips are disposed in the base substrate 400 (or the redistribution layer 500), and the outer posts 800 may be electrically connected to the plurality of chips, so that the number of signal transmission paths of the plurality of chips may be determined and the heat emission efficiency may be increased.

In some embodiments, a disposition of the outer connection pad 413 and chip pads illustrated in FIG. 2 may be appropriately changed and implemented. In various example embodiments of the present disclosure, positions of the outer connection pad 413 and the chip pads are not limited to the illustrations provided in the figures.

In some example embodiments, the outer post 800 may have a cylindrical shape, a quadrangular pillar shape, or a polygonal pillar shape. However, the outer post 800 may be formed in various shapes penetrating or extending into the first molding film 710 in addition to the above-described shapes.

In some example embodiments, in order to perform signal transmission and heat transfer operations, the outer post 800 may be formed to be sufficiently thick. Here, a thickness of the outer post 800 may be a length of the outer post 800 in a direction perpendicular to the first direction D1. For example, referring to FIG. 3, a thickness d1 of the outer post 800 may be larger than a thickness d2 of the wiring post 911 which connects a chip and the base substrate 400. As such, the thickness of the outer post 800 may be formed to be larger than that of the wiring post 911, so that an effect of the signal transmission and heat emission through the outer post 800 may be maximized.

However, the thickness d1 of the outer post 800 is not limited to the above description and may be formed to be equal to or smaller than the thickness d2 of the wiring post 911.

In some example embodiments, the semiconductor package 10 may include a connection post 920. In some example embodiments, the connection post 920 may penetrate or extend into the first molding film 710 to be electrically connected to each of the base substrate 400 and the redistribution layer 500. For example, the connection post 920 may be for electric connection between the redistribution layer 500 and the base substrate 400. For example, the connection post 920 may be for signal transmission between the base substrate 400 and the second chip group 200 which is disposed above the redistribution layer 500.

In some example embodiments, unlike the outer post 800, the connection post 920 may be disposed at a position overlapping at least a portion of the second chip group 200 in the first direction D1. For example, referring to FIG. 1, while not overlapping (or being free from overlap with) the first chip group 100 in the first direction D1, the connection post 920 may be disposed at the position overlapping the second chip group 200 in the first direction D1.

In some example embodiments, the connection post 920 may include a metal such as copper (Cu) that is electrically conductive.

In some example embodiments, the connection post 920 may be disposed in a connection area 400c on the base substrate 400. For example, referring to FIG. 2, the connection area 400c at a side of the chip area 400a on the base substrate 400, and a plurality of connection pads 414 to which connection posts 920 are individually disposed may be formed in the connection area 400c.

Referring to FIG. 2, the connection area 400c may be formed at one side of the chip area 400a, the outer area 400b may be formed at a portion at which the connection area 400c is not formed around the chip area 400a. As such, a remaining area other than the chip area 400a and the connection area 400c on the base substrate 400 may be used as the outer area 400b in which the outer post 800 is disposed, so that the signal area for transmitting and receiving a signal to and from an outside may be expanded, and a thermal property may be improved by improving the heat emission efficiency while an entire thickness of the semiconductor package 10 is maintained relatively thin.

In some example embodiments, one of a plurality of external connection terminal 430 may be electrically connected to the signal post, and another one thereof may be electrically connected to the thermal post. The external connection terminal 430 which is electrically connected to the signal post may serve as a terminal for signal transmission. The external connection terminal 430 which is electrically connected to the thermal post may serve as a terminal for heat transfer.

As describe above, each of a plurality of signal pads 111a and 121a may be electrically separated, and accordingly, external connection terminals individually connected to the signal pads 111a and 121a (namely, terminals for signal transmission) may be maintained to be electrically separated from each other.

In some embodiments, some thermal pads of the plurality of thermal pads 111b and 121b may be electrically connected to each other, and in this case, the thermal pads electrically connected to each other may be electrically connected to one or more terminals for heat transfer.

In some example embodiments, referring to FIGS. 1 and 3, a thickness t2 of the redistribution layer 500 may be smaller than a thickness t1 of the base substrate 400. The thickness of the redistribution layer 500 may be formed relatively thinly, so that the entire thickness of the semiconductor package 10 may be minimized.

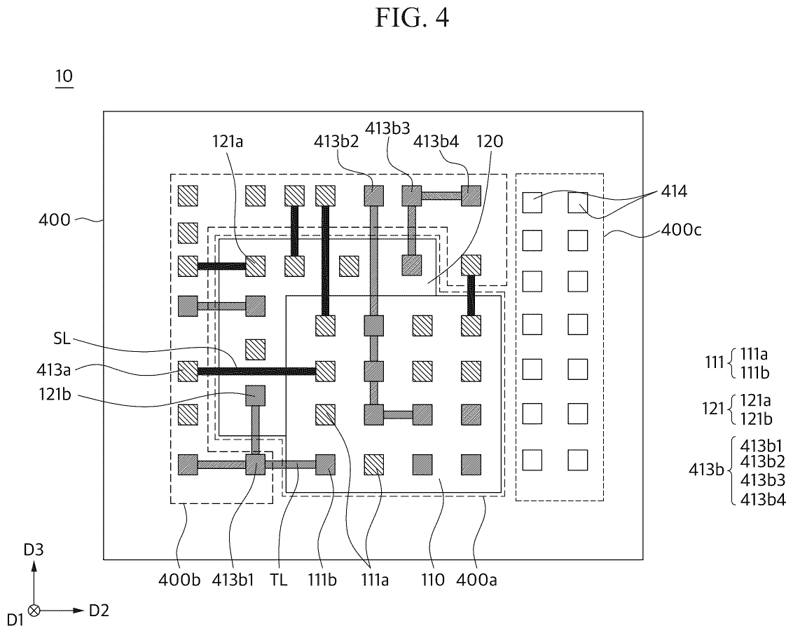

FIG. 4 is an example cross-sectional diagram illustrating the semiconductor package 10 according to some example embodiments.

Similarly to FIG. 2, FIG. 4 is a cross-sectional diagram of the semiconductor package 10 which is viewed from an upper surface of the base substrate 400 in the first direction D1. The first chip 110, the second chip 120, the first chip pad 111, and the second chip pad 121 which are illustrated in FIG. 4 may be understood as being projected on the cross-sectional diagram.

Referring to FIG. 4, in various example embodiments, first outer connection pad 413a may be electrically connected to each of the signal pads 111a and 121a and the second outer connection pad 413b may be electrically connected to each of the thermal pads 111b and 121b. The outer post 800 may be disposed on each of the first outer connection pad 413a and the second outer connection pad 413b.

In various example embodiments, a plurality of thermal pads may be electrically connected to one second outer connection pad 413b. For example, referring to FIG. 4, the plurality of thermal pads may be connected together to one second outer connection pad 413b2. Thus, one thermal post disposed on the second outer connection pad 413b may be electrically connected to all the plurality of thermal pads to function as a heat emission path connected to the plurality of thermal pads.

In some embodiments, referring to FIG. 4 both of the first thermal pad 111b of the first chip 110 and the second thermal pad 121b of the second chip 120 may be connected to one second outer connection pad 413b1. Thus, one thermal post disposed on the second outer connection pad 413b1 may be electrically connected to both of the first thermal pad 111b of the first chip 110 and the second thermal pad 121b of the second chip 120 to function as a heat emission path connected to all of a plurality of chips.

In some example embodiments, one thermal pad may be electrically connected to a plurality of second outer connection pads 413b3 and 413b4. For example, two neighboring second outer connection pads 413b3 and 413b4 may be directly connected to each other, and one thermal pad may be directly connected to at least one of the two second outer connection pads 413b3 and 413b4. Accordingly, two or more thermal posts may be electrically connected to one thermal pad. As such, a plurality of thermal posts may be connected to a thermal pad near a portion at which heat is emitted, so that heat emission efficiency may be maximized.

However, a connection relationship between the outer connection pads 413a and 413b and the chip pads 111 and 121 illustrated in FIG. 4 is merely an example, and the outer connection pads 413a and 413b and the chip pads 111 and 121 may be connected in various patterns in addition thereto.

In some embodiments, when compared to FIG. 2, a position of disposition of and a relationship of connection between the chip pads 111 and 121 and the outer connection pads 413a and 413b are changed in some example embodiments illustrated in FIG. 4, and a description with reference to FIGS. 1 through 3 may be referenced for all other descriptions other than the above description.

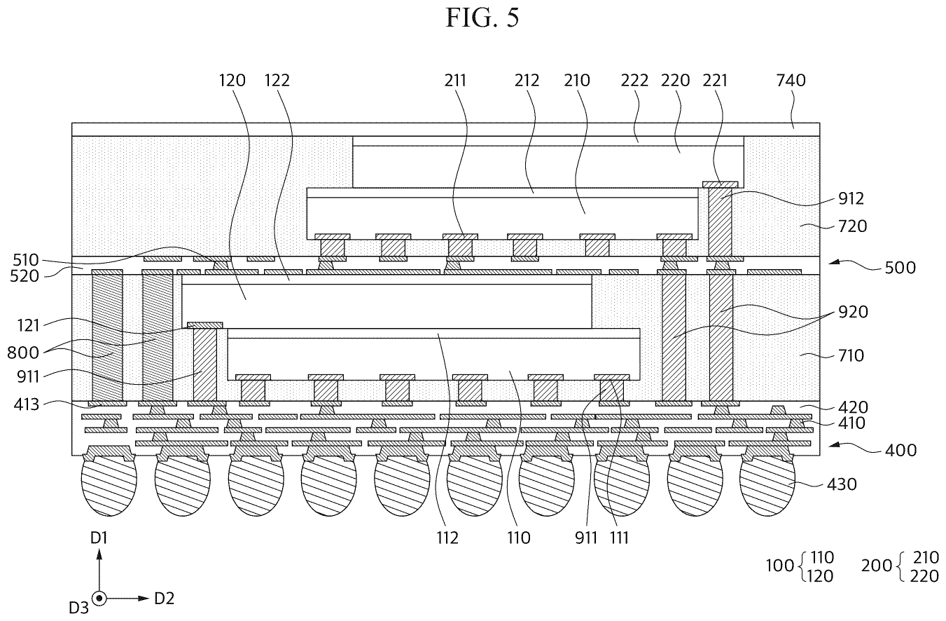

FIG. 5 is an example cross-sectional diagram illustrating the semiconductor package 10 according to some example embodiments.

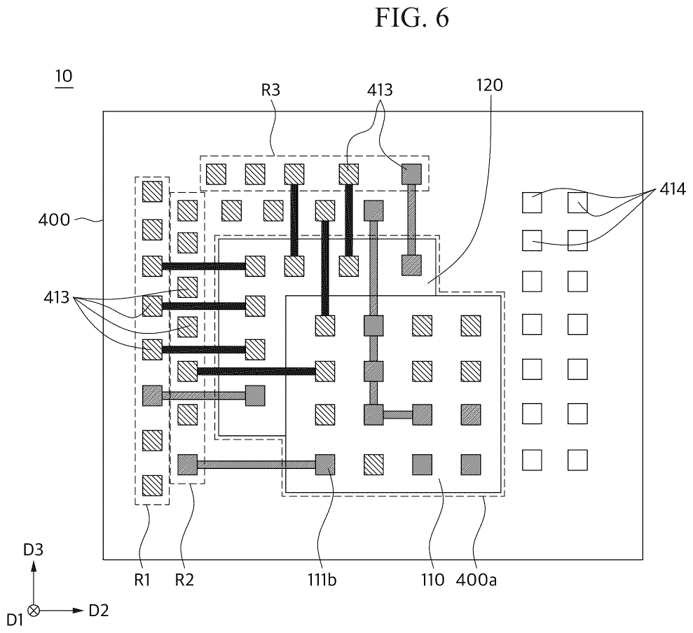

FIG. 6 is an example cross-sectional diagram illustrating the semiconductor package 10 according to some example embodiments.

In various example embodiments, the plurality of outer posts 800 which are included in the semiconductor package 10 may be disposed in a plurality of rows or columns at a side of a chip group.

Referring to FIGS. 5 and 6 together, the base substrate 400 may include the plurality of outer connection pads 413 to which the outer posts 800 are individually disposed. The plurality of outer connection pads 413 may include a plurality of outer connection pads 413 disposed to form a first row R1 in the third direction D3 parallel to an upper surface of the base substrate 400 and a plurality of outer connection pads 413 disposed to form a second row R2 parallel to the first row R1.

In various example embodiments, the plurality of outer posts 800 may include a first row outer post disposed on the outer connection pad 413 which forms the first row R1 and a second row outer post disposed on the outer connection pad 413 which forms the second row R2. That is, with respect to the plurality of outer posts 800, the first row outer post may be disposed to form the first row R1 in the third direction D3 parallel to the upper surface of the base substrate 400, and the second row outer post may be disposed to form the second row R2 parallel to the first row R1.

Also, in various example embodiments, a portion of the plurality of outer connection pads 413 of the semiconductor package 10 may be disposed to form a third row R3 perpendicular to the first row R1. In other words, the semiconductor package 10 may further include a plurality of third row outer posts disposed to form the third row R3 perpendicular to the first row R1.

In various example embodiments, the plurality of outer posts 800 may be a signal post or a thermal post. For example, a portion of outer posts 800 forming the first row R1 may be the signal post which is connected to a signal pad, and another portion thereof may be the thermal post which is connected to a thermal pad.

Multiple outer posts 800 may be disposed to an outside of the chip area 400a, so that a large number of signal posts and thermal posts may be secured. Accordingly, a signal area of the semiconductor package 10 may be expanded, and thermal performance may be improved.

In various example embodiments, referring to FIG. 6, the outer connection pad 413 which forms the first row R1 and the outer connection pad 413 which forms the second row R2 may be staggered or offset from each other in a direction perpendicular to an extension direction of the first row R1 (e.g., the third direction D3), for example, in the second direction D2. That is, the outer post 800 which forms the first row R1 and the outer post 800 which forms the second row R2 may be staggered or offset from each other in a direction perpendicular to the first row R1 (for example, in the second direction D2). As such, outer posts 800 in different rows may be staggered or offset from each other, so that a signal line or a thermal line from one outer post 800 (or one outer connection pad 413) to a chip pad may be formed to have a shortest distance without interfering with another outer post 800 (or another outer connection pad 413).

In various example embodiments, a connection pad 414 to which the connection post 920 is disposed may be staggered or offset from the outer connection pad 413 which forms the first row R1 in a direction perpendicular to the first direction D1 (for example, in the second direction D2).

However, a position of disposition of the outer connection pad 413 or a relationship of connection between the outer connection pad 413 and a chip pad illustrated in FIGS. 5 and 6 is merely an example. The outer connection pad 413 and the chip pad may be connected in various patterns.

Meanwhile, when compared to FIGS. 1 through 4, the position of the disposition of and the relationship of the connection between the chip pad and the outer connection pad 413 are changed in some example embodiments illustrated in FIGS. 5 and 6, and a description with reference to FIGS. 1 through 4 may be referenced for all other descriptions other than the above description.

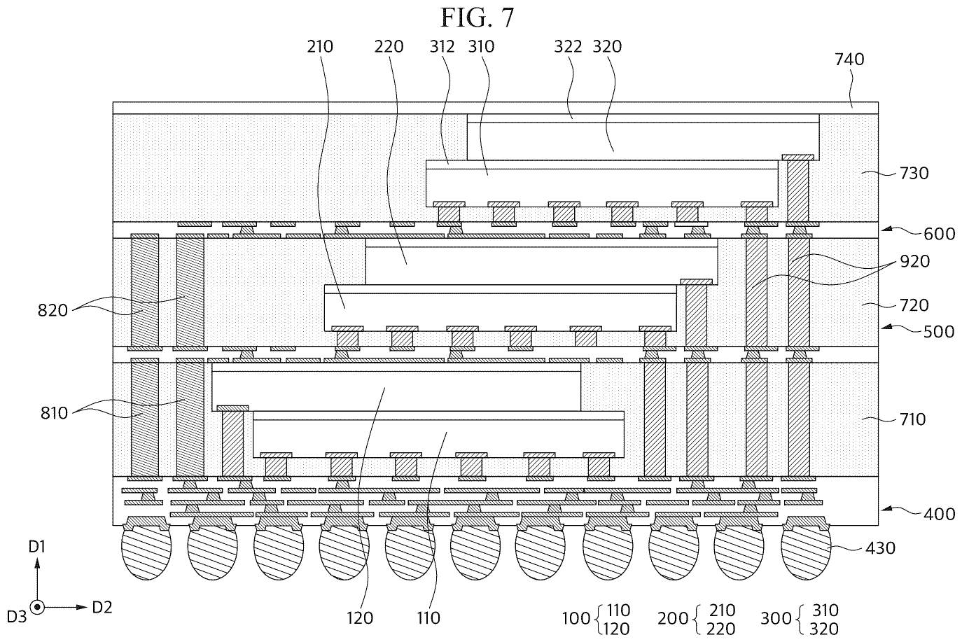

FIG. 7 is an example cross-sectional diagram illustrating the semiconductor package 10 according to some example embodiments.

In various example embodiments, the semiconductor package 10 may further include a third chip group 300. For example, referring to FIG. 7, a redistribution layer 600 may be on an upper side of the second molding film 720 which surrounds or extends around the second chip group 200, and the third chip group 300 may be disposed above the redistribution layer 600.

For distinction from the redistribution layer 500 above which the second chip group 200 is disposed, in the following description, the redistribution layer 500 disposed between the first molding film 710 and the second molding film 720 will be referred to as a first redistribution layer 500, and the redistribution layer 600 disposed at the upper side of the second molding film 720 may be referred to as a second redistribution layer 600. In this case, the first redistribution layer 500 may correspond to the redistribution layer 500 described above through FIGS. 1 through 6.

In various example embodiments, the third chip group 300 which includes a plurality of chips 310 and 320 may be disposed above the second redistribution layer 600. For example, referring to FIG. 7, the third chip group 300 may include a fifth chip 310 and a sixth chip 320 disposed above the redistribution layer 600. The fifth chip 310 may be fixed to the sixth chip 320 through a fifth adhesive member 312, and the sixth chip 320 may be fixed to an insulation film 740 through a sixth adhesive member 322. FIG. 7 illustrates that the third chip group 300 includes two chips, but it is merely an example. For example, the third chip group 300 may include only one chip or three or more chips.

In various example embodiments, the plurality of chips 310 and 320 included in the third chip group 300 may be disposed so that a surface on which a chip pad is disposed faces the second redistribution layer 600. For example, referring to FIG. 7 the fifth chip 310 and the sixth chip 320 may be electrically connected to the second redistribution layer 600 in a state in which the surface on which the chip pad is formed is disposed to face the second redistribution layer 600.

In various example embodiments, similarly to the first chip group 100, a plurality of chip pads of the third chip group 300 may include a signal pad used to transmit a signal to an outside and a thermal pad used to transfer heat generated in a chip to the outside. Descriptions of a signal pad and a thermal pad of the first chip group 100 may be referenced for the signal pad and the thermal pad of the third chip group 300.

In some example embodiments, as the chip pad and a wiring post connected to the second redistribution layer 600 are electrically connected to each other, the plurality of chips 310 and 320 included in the third chip group 300 may be electrically connected to the redistribution layer 500.

In various example embodiments, similarly to the first chip group 100, the plurality of chips 310 and 320 of the third chip group 300 may be stacked to be offset from each other in the second direction D2 and/or the third direction D3. A description of the first chip group 100 may be referenced for a structure of offset disposition of the third chip group 300 and disposition and the number of the chip pads according thereto.

Also, the description of the first chip group 100 may be referenced for types of the plurality of chips 310 and 320 of the third chip group 300.

In various example embodiments, a third molding film 730 may be disposed to surround or extend around the third chip group 300 at an upper side of the second redistribution layer 600. The third molding film 730 may include an insulation material. For example, the third molding film 730 may include an insulating polymer material such as an epoxy molding compound (EMC). In some embodiments, the third molding film 730 may include a thermosetting resin such as an epoxy resin or a thermoplastic resin such as polyimide.

In some example embodiments, the third molding film 730 may be formed of a material different from that of the first molding film 710. In some example embodiments, the third molding film 730 may be formed of a material different from that of the second molding film 720.

In various example embodiments, the semiconductor package 10 may include a plurality of outer posts 810 and 820 disposed to an outside of the first chip group 100 or an outside of the second chip group 200.

In various example embodiments, the plurality of outer posts 810 and 820 may include a first outer post 810 electrically connected to each of the base substrate 400 and the first redistribution layer 500 by penetrating or extending into the first molding film 710 and a second outer post 820 electrically connected to each of the first redistribution layer 500 and the second redistribution layer 600 by penetrating or extending into the second molding film 720. Here, the first outer post 810 may correspond to the outer post 800 described above with reference to FIGS. 1 through 6.

In addition, referring to FIG. 7, the second outer post 820 may extend from an upper surface of the first redistribution layer 500 to the second redistribution layer 600 in the first direction D1 and may be disposed to penetrate or extend into the second molding film 720.

In various example embodiments, the plurality of outer posts 810 and 820 may be disposed at positions such that they are free from overlap with, in the first direction D1, all of a plurality of chip groups included in the semiconductor package 10. For example, referring to FIG. 7, the first outer post 810 and the second outer post 820 may be disposed at positions free from overlap with the first chip group 100, the second chip group 200, and the third chip group 300 in the first direction D1.

In various example embodiments, the first outer post 810 and the second outer post 820 may be disposed to at least partially overlap each other in the first direction D1. However, in some embodiments, the first outer post 810 and the second outer post 820 may be staggered or offset from each other in the first direction D1.

In various example embodiments, the first outer post 810 and the second outer post 820 may be connected to each other through the first redistribution layer 500.

In some example embodiments, the first outer post 810 and the second outer post 820 may be variously disposed to be in contact with each other. For example, one of the first outer post 810 and the second outer post 820 may penetrate or extend into the first redistribution layer 500 to be in contact with and connected to another one. In this case, as the first outer post 810 and the second outer post 820 are in direct contact with each other, signal transmission speed and heat transfer speed may be improved.

In various example embodiments, the second outer post 820 may be electrically connected to the second chip group 200 through the first redistribution layer 500. In addition, the second outer post 820 may be also electrically connected to the third chip group 300 through the second redistribution layer 600.

In various example embodiments, one of second outer posts 820 may be electrically connected to a signal pad or a thermal pad of the second chip group 200. In some embodiments, one of the second outer posts 820 may be electrically connected to the signal pad or the thermal pad of the third chip group 300. Accordingly, the second outer post 820 may serve as a signal post or a thermal post connected to the second chip group 200 or a signal post or a thermal post connected to the third chip group 300. Here, the configurations of the signal post and the thermal post described above with reference to FIGS. 1 through 3 may be referenced for configurations of the signal post and the thermal post.

As shown in FIG. 7, when a large number of chip groups are stacked in the first direction D1, outer posts 810 and 820 may be provided in each layer, so that a thermal property may be effectively improved while a signal area is sufficiently secured.

In various example embodiments, the semiconductor package 10 may include the connection post 920. Some connection posts 920 among a plurality of connection posts 920 may be electrically connected to each of the base substrate 400 and the first redistribution layer 500 by penetrating or extending into the first molding film 710, and some other connection posts 920 may be electrically connected to each of the first redistribution layer 500 and the second redistribution layer 600 by penetrating or extending into the second molding film 720.

In various example embodiments, the connection post 920 may be disposed at a position at least partially overlapping, in the first direction D1, at least one chip group among multiple chip groups included in the semiconductor package 10.

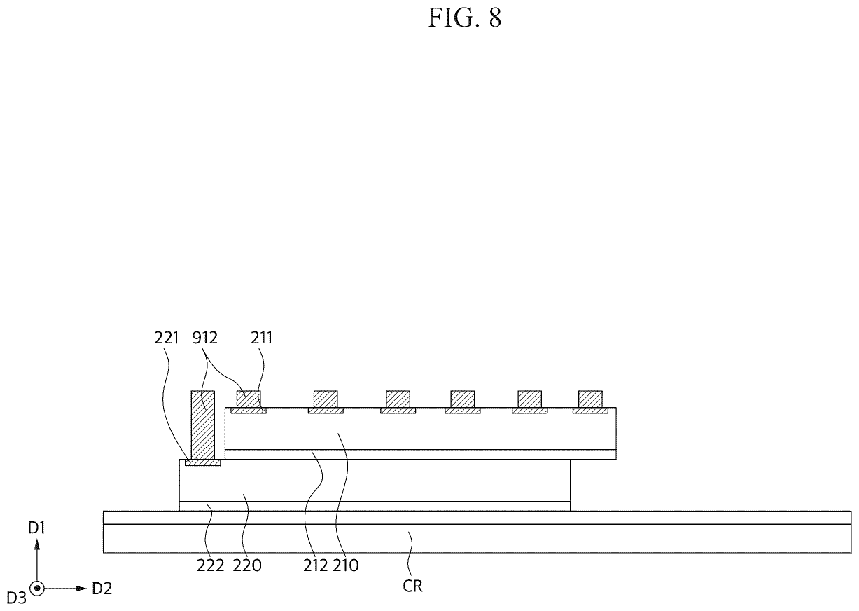

Hereinafter, a method of manufacturing the semiconductor package 10 according to some example embodiments will be described with reference to FIGS. 8 through 14. FIGS. 8 through 14 illustrate an example of each operation of a method of manufacturing the semiconductor package 10 according to some example embodiments.

FIG. 8 is a cross-sectional diagram illustrating that the second chip group 200 is aligned on a carrier CR.

Referring to FIG. 8, the insulation film 740 is formed on the carrier CR, and the third chip 210 and the fourth chip 220 may be disposed above the insulation film 740. The fourth adhesive member 222 may be interposed between the fourth chip 220 and the insulation film 740, and the third adhesive member 212 may be interposed between the third chip 210 and the fourth chip 220.

In example embodiments, when the third adhesive member 212 and the fourth adhesive member 222 are provided as an adhesive film, the adhesive film may be attached, in a state of being half cured, to a wafer before being sawed or cut into a chip, and then may be sawed or cut together with the chip in a process in which the wafer is divided into each chip. Thus, the adhesive film may have an area corresponding to the chip to which the adhesive film is attached.

In example embodiments, the adhesive film may be a thermosetting adhesive film. In this case, the adhesive film may be heated and cured in a state of being tightly attached to a surface for attaching, so that the third chip 210 and the fourth chip 220 may be bonded.

In some example embodiments, the third chip 210 and the fourth chip 220 may be aligned so that the third chip pad 211 and the fourth chip pad 221 are at least partially exposed in a direction opposite to a direction from the third chip 210 and the fourth chip 220 toward the carrier CR.

In some example embodiments, in a state in which the third chip 210 and the fourth chip 220 are aligned, the wiring post 912 may be connected to the third chip pad 211 and the fourth chip pad 221.

In some example embodiments, the wiring post 912 may be formed of a conductive metallic material and may be formed to extend in the first direction D1 on the third chip pad 211 and the fourth chip pad 221.

In some example embodiments, the third chip pads 211 may be disposed in a plurality of rows and columns throughout an entire area of an upper surface of the third chip 210. As such, multiple chip pads may be disposed in an entire area of a surface exposed on an upper side of the third chip 210, so that a wide signal area and heat emission area may be secured.

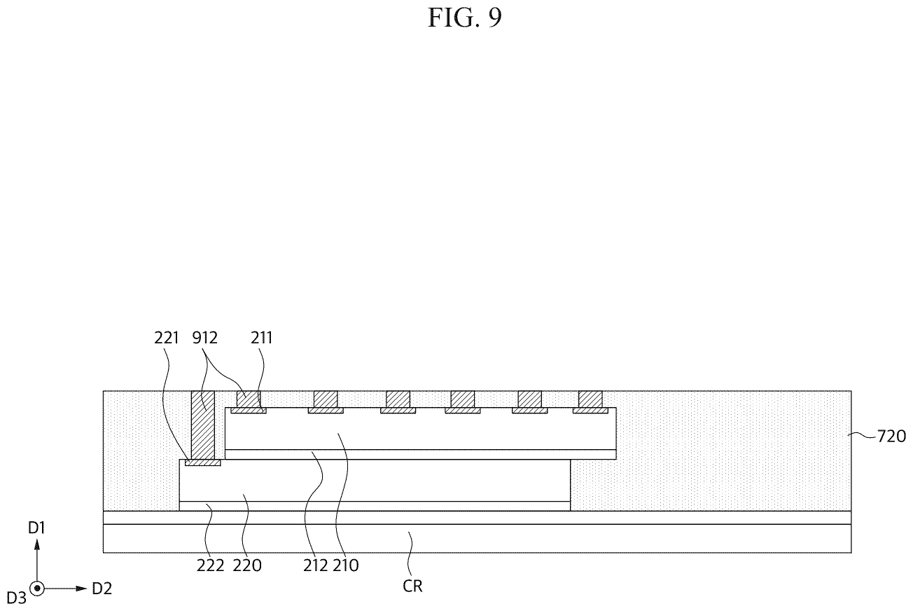

FIG. 9 is a cross-sectional diagram illustrating that the second molding film 720 surrounds the second chip group 200.

Referring to FIG. 9, the second molding film 720 may be formed to surround or extend around the second chip group 200.

In some example embodiments, a process of forming the second molding film 720 may include a compression molding process or a transfer molding process.

In some example embodiments, the second molding film 720 may be formed to a degree to which the third chip 210 and the fourth chip 220 are sufficiently covered or overlapped and then may be grinded to have an appropriate thickness.

In a griding process, a portion of the second molding film 720 and a portion of the wiring post 912 may be removed, and when the grinding process is completed, an end portion of the wiring post 912 may be at least partially exposed on a planar upper surface of the second molding film 720.

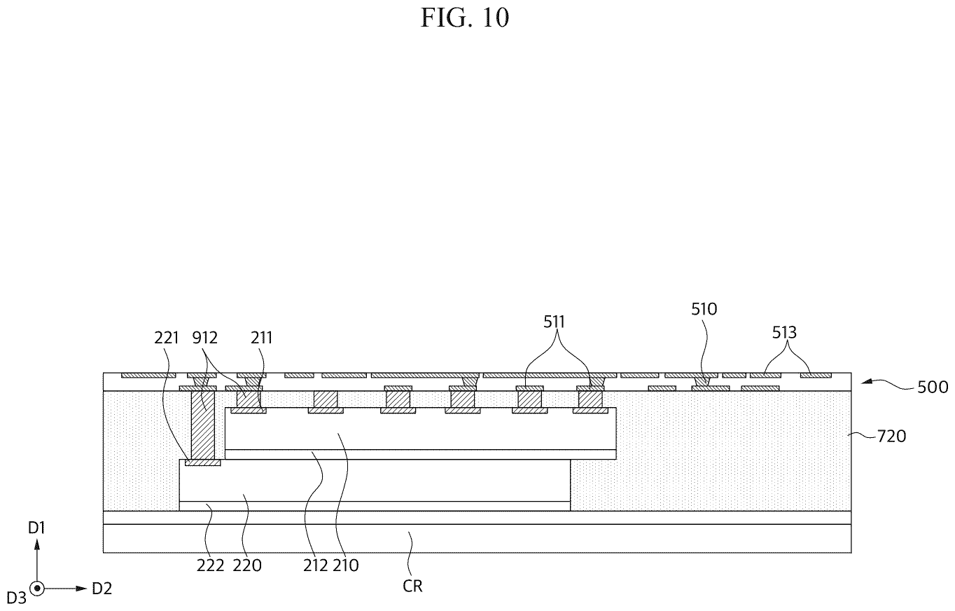

FIG. 10 is a cross-sectional diagram illustrating that the redistribution layer 720 is formed on the second molding film 500.

Referring to FIG. 10, the redistribution layer 500 may be formed on a planar upper surface of the second molding film 720.

In some example embodiments, the redistribution layer 500 may include the redistribution insulation film 520 and the redistribution structure 510.

In some example embodiments, the redistribution structure 510 of the redistribution layer 500 may be formed to be electrically connected to wiring posts 912 of the third chip 210 and the fourth chip 220. For example, the redistribution layer 500 may be formed by alternately repeating processes of forming a metallic pattern so that the metallic pattern is electrically connected to the wiring post 912 at least partially exposed through or by the upper surface of the second molding film 720 and forming, on an upper side thereof, an insulation layer including an inorganic dielectric such as a polymer or silicon oxide.

In some example embodiments, the metallic pattern may be formed in a scheme of performing an electrolytic plating process after a seed metallic layer is formed or by performing a sputtering process.

In some example embodiments, the insulation layer may be formed through a process such as chemical vapor deposition (CVD), atomic layer deposition (ALD), or plasma-enhanced chemical vapor deposition (PECVD).

In some example embodiments, the outer connection pad 513 may be formed on a surface of the redistribution layer 500, which is opposite to a surface thereof in contact with the second molding film 720. The outer post 800 may be connected to the outer connection pad 513 in the following operation.

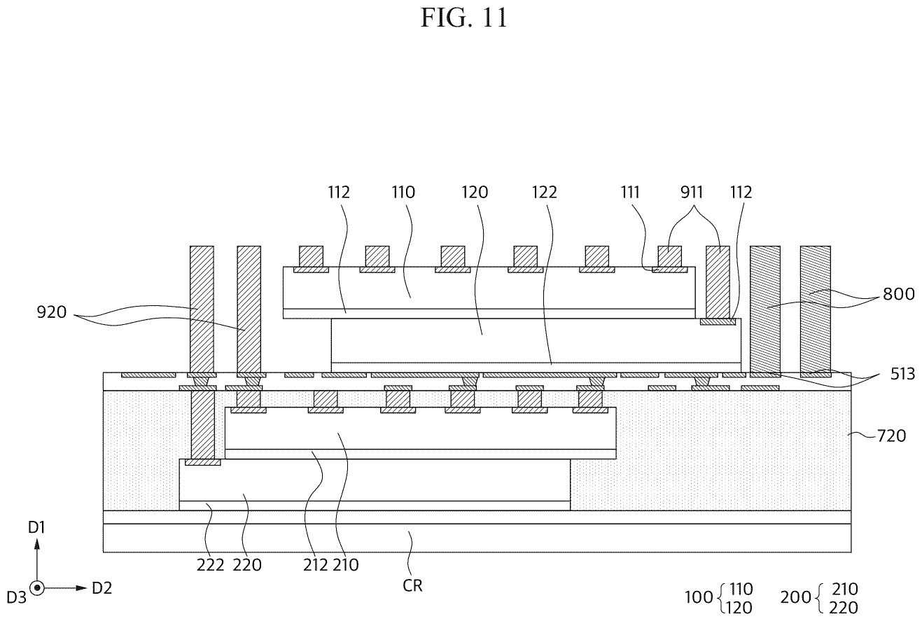

FIG. 11 is a cross-sectional diagram illustrating that the first chip group 100 is aligned on the redistribution layer 500 and that the outer post 800 and the connection post 920 are formed.

Referring to FIG. 11, the first chip group 100 may be formed above the redistribution layer 500. The first adhesive member 112 may be interposed between the first chip 110 and the second chip 120, and the second adhesive member 122 may be interposed between the second chip 120 and the redistribution layer 500. The above descriptions of the third adhesive member 212 and the fourth adhesive member 222 of FIG. 8 may be referenced for a disposition method, a bonding method, or the like for the first adhesive member 112 and the second adhesive member 122.

In some example embodiments, the first chip 110 and the second chip 120 may be aligned so that the first chip pad 111 and the second chip pad 121 are at least partially exposed toward an upper side.

In some example embodiments, in a state in which the first chip 110 and the second chip 120 are aligned, the wiring post 911 may be connected to the first chip pad 111 and the second chip pad 121.

In some example embodiments, the wiring post 911 may be formed of a conductive metallic material and may be formed to extend in the first direction D1 on the first chip pad 111 and the second chip pad 121.

In some example embodiments, the first chip pads 111 may be disposed in a plurality of rows and columns throughout an entire area of an upper surface of the first chip 110. As such, multiple chip pads may be disposed in the entire area of the surface exposed on an upper side of the first chip 110, so that a wide signal area and heat emission area may be secured.

In some example embodiments, the connection post 920 and the outer post 800 may be formed at sides of the first chip group 100.

In some example embodiments, the connection post 920 may be disposed at a position overlapping at least a portion of the second chip group 200 in the first direction D1.

In some example embodiments, the outer post 800 may be formed on the outer connection pad 513 of the redistribution layer 500 and disposed at a position free from overlap with the second chip group 200 in the first direction D1.

In some example embodiments, the outer post 800 may be electrically connected to the outer connection pad 513 of the redistribution layer 500 and electrically connected to a signal pad or a thermal pad of the second chip group 200.

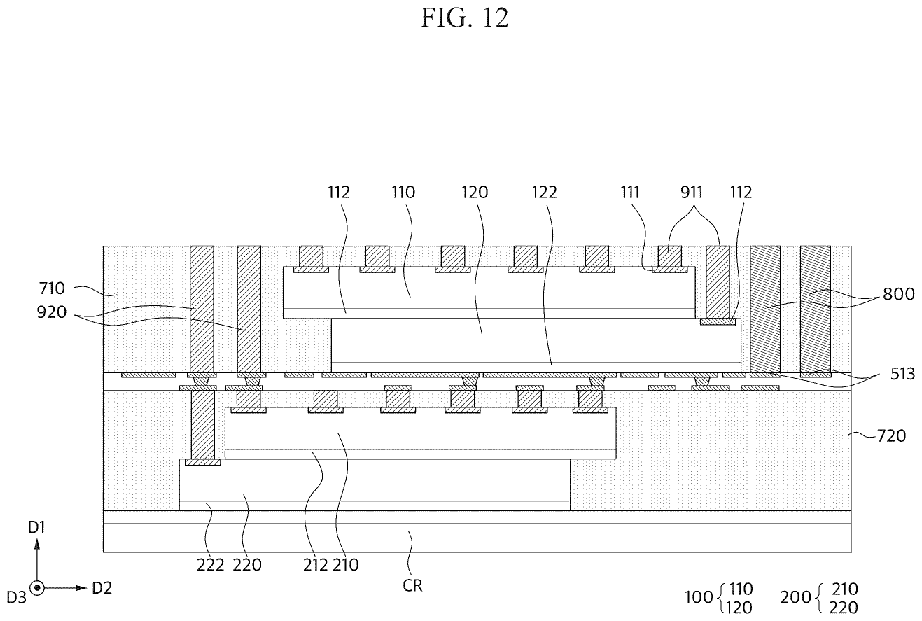

FIG. 12 is a cross-sectional diagram illustrating that the first molding film 710 is formed on the redistribution layer 500.

Referring to FIG. 12, the first molding film 710 may be formed to surround or extend around the first chip group 100.

In some example embodiments, a process of forming the first molding film 710 may include a compression molding process or a transfer molding process.

In some example embodiments, the first molding film 710 may be formed to a degree to which the first chip 110 and the second chip 120 are sufficiently covered or overlapped and then may be grinded to have an appropriate thickness.

In a griding process, a portion of the first molding film 710 and a portion of the wiring post 911 may be removed, and when the grinding process is completed, an end portion of the wiring post 911 may be at least partially exposed by a planar upper surface of the first molding film 710.

In some example embodiments, the first molding film 710 may be formed of a material different from that of the second molding film 720. As such, chip groups may be individually at least partially surrounded with molding films formed of different materials, so that a molding film that is desirable for a property of each chip group may be formed.

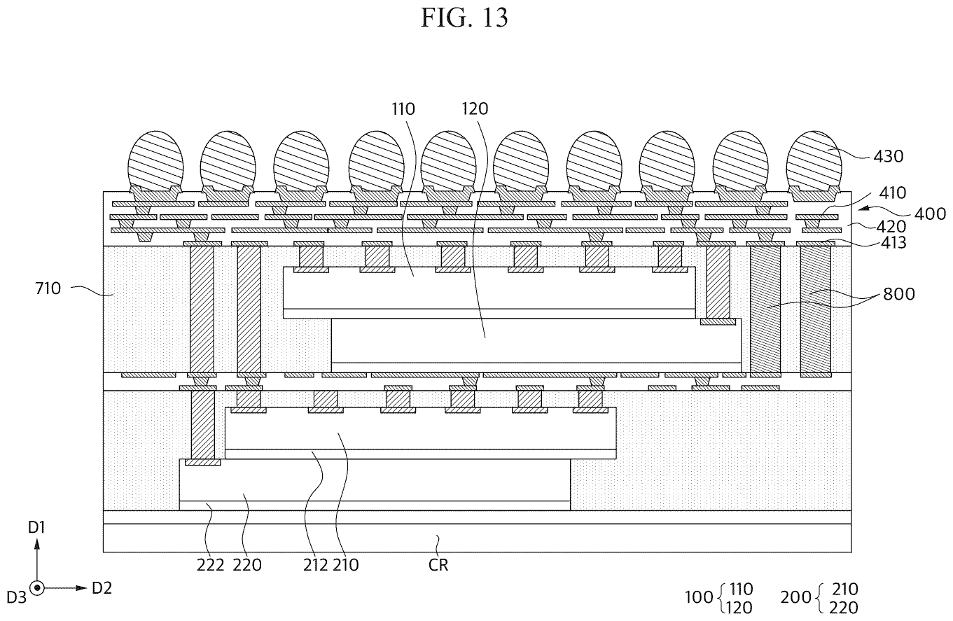

FIG. 13 is a cross-sectional diagram illustrating that the base substrate 400 is formed on the first molding film 710.

Referring to FIG. 13, the base substrate 400 may be formed on a planar upper surface of the first molding film 710.

In some example embodiments, the base substrate 400 may be a redistribution substrate formed through a redistribution process and may include the redistribution insulation film 420 and the redistribution structure 410.

In some example embodiments, the redistribution structure 410 of the redistribution substrate may be formed to be electrically connected to wiring posts 911 of the first chip 110 and the second chip 120. For example, the redistribution layer 500 may be formed by alternately repeating processes of forming a metallic pattern so that the metallic pattern is electrically connected to the wiring post 911 at least partially exposed through or by the upper surface of the first molding film 710 and forming, on an upper side thereof, an insulation layer including an inorganic dielectric such as a polymer or silicon oxide.

In some example embodiments, the metallic pattern may be formed in a scheme of performing an electrolytic plating process after a seed metallic layer is formed or by performing a sputtering process.

In some example embodiments, the insulation layer may be formed through a process such as chemical vapor deposition (CVD), atomic layer deposition (ALD), or plasma-enhanced chemical vapor deposition (PECVD).

Meanwhile, in various example embodiments, the base substrate 400 may be a printed circuit board (PCB) or a ceramic substrate. In some embodiments, the base substrate 400 may be a wiring structure for a wafer level package (WLP) manufactured at a wafer level.

In some example embodiments, the external connection terminal 430 may be formed on a surface of the redistribution layer 400, which is opposite to a surface thereof in contact with the first molding film 710.

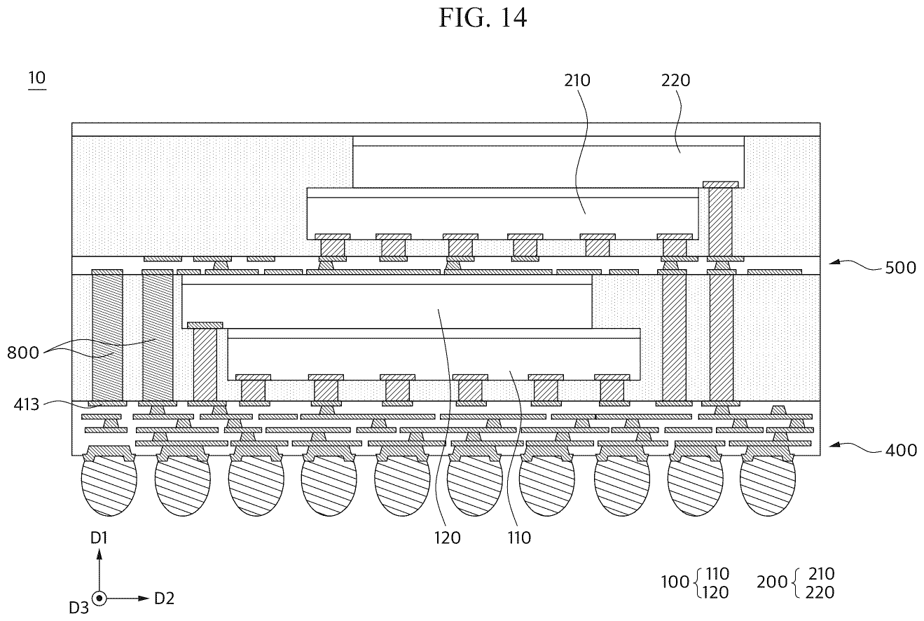

FIG. 14 is a cross-sectional diagram illustrating that the semiconductor package 10 is separated from the carrier CR.

Referring to FIG. 14, the carrier CR is removed, and the complete semiconductor package 10 is reversed, so that the external connection terminal 430 is disposed downward. In this case, the semiconductor package 10 may be sawed or cut to an appropriate size.

Since the semiconductor package 10 manufactured through a manufacturing method described through FIGS. 8 through 14 corresponds to the semiconductor package 10 described above through FIGS. 1 through 3, a description with reference to FIGS. 1 through 3 may be referenced for other details not described through FIGS. 8 through 14.

The various example embodiments of the present disclosure have been described above in detail, but the scope of the present disclosure is not limited thereto. It will be apparent to those skilled in the art that various changes and modifications may be allowed within the range of the present disclosure. In addition, the above-described example embodiments may be implemented without a portion of elements thereof, and each of the example embodiments may be implemented in combination with another. It will be apparent to those skilled in the art that various modifications and changes may be made within the scope of the appended claims and their equivalents.

What is claimed is:

1. A semiconductor package comprising:
a base substrate;
a first chip on the base substrate;
a second chip on the first chip;
a molding film extending around the first chip and the second chip;
a redistribution layer on an upper surface of the molding film; and
a plurality of outer posts that are on side surfaces of at least one of the first chip or the second chip, are electrically connected to the base substrate and the redistribution layer, and extend into the molding film,
wherein the first chip or the second chip comprises:
a signal pad through which one or more electrical signals are transmitted; and
a thermal pad configured to dissipate heat away from the semiconductor package, and
wherein the plurality of outer posts comprise a signal post electrically connected to the signal pad or a thermal post electrically connected to the thermal pad.

2. The semiconductor package of claim 1, wherein the signal pad and the thermal pad are on a surface of the first chip that faces the base substrate or a surface of the second chip that faces the base substrate.

3. The semiconductor package of claim 1, further comprising a plurality of thermal pads that comprise the thermal pad, wherein the plurality of outer posts comprise at least one thermal post, and wherein the at least one thermal post is electrically connected to the plurality of thermal pads.

4. The semiconductor package of claim 1, wherein the plurality of outer posts comprise a plurality of thermal posts, and wherein at least two thermal posts of the plurality of thermal posts are electrically connected to the thermal pad.

5. The semiconductor package of claim 1, further comprising a wiring post in contact with the signal pad or the thermal pad, wherein a thickness of each of the plurality of outer posts is greater than a thickness of the wiring post.

6. The semiconductor package of claim 1, wherein the plurality of outer posts comprise:
a plurality of first row outer posts that define a first row in a first direction that is parallel to an upper surface of the base substrate; and
a plurality of second row outer posts that define a second row parallel to the first row.

7. The semiconductor package of claim 6, wherein the plurality of first row outer posts and the plurality of second row outer posts are offset from each other in a second direction that is perpendicular to the first direction.

8. The semiconductor package of claim 6, wherein the plurality of outer posts further comprise a plurality of third row outer posts that define a third row that is perpendicular to the first row.

9. The semiconductor package of claim 1, wherein:
the first chip comprises a plurality of first chip pads that face the base substrate,
the second chip comprises a plurality of second chip pads that face the base substrate, and
a number of the plurality of first chip pads is greater than a number of the plurality of second chip pads.

10. A semiconductor package comprising:
a base substrate;
a first chip group comprising a plurality of first chips on the base substrate;
a first molding film extending around the first chip group;
a first redistribution layer on the first molding film;
a second chip group comprising a plurality of second chips on the first redistribution layer; and
a plurality of first outer posts electrically connected to the base substrate and the first redistribution layer, and extending into the first molding film,
wherein the plurality of first outer posts are free from overlap with the first chip group and the second chip group in a first direction perpendicular to an upper surface of the base substrate, and
wherein at least one first outer post of the plurality of first outer posts is electrically connected to at least one second chip of the plurality of second chips through the first redistribution layer.

11. The semiconductor package of claim 10, wherein the at least one second chip comprises a signal pad and a thermal pad, and
wherein the at least one first outer post comprises a signal post electrically connected to the signal pad or a thermal post electrically connected to the thermal pad and electrically insulated from the signal pad.

12. The semiconductor package of claim 11, further comprising a wiring post in contact with the signal pad or the thermal pad,
wherein a thickness of each of the plurality of first outer posts is greater than a thickness of the wiring post.

13. The semiconductor package of claim 11, wherein the plurality of first outer posts comprise a plurality of thermal posts, and wherein at least two thermal posts of the plurality of thermal posts are electrically connected to each other.

14. The semiconductor package of claim 10, further comprising a connection post that extends into the first molding film and at least partially overlaps the second chip group in the first direction,
wherein the connection post is electrically connected to the at least one second chip through the first redistribution layer.

15. The semiconductor package of claim 14, wherein the plurality of first outer posts comprise:
a plurality of first row outer posts that define a first row in a second direction parallel to the upper surface of the base substrate; and
a plurality of second row outer posts that define a second row that is parallel to the first row and offset from the first row outer posts in a third direction that is perpendicular to the first row.

16. The semiconductor package of claim 15, wherein the connection post is offset from the first row outer posts in the third direction.

17. The semiconductor package of claim 10, further comprising a second molding film extending around the second chip group,
wherein a material of the second molding film is different from a material of the first molding film.

18. The semiconductor package of claim 10, wherein the plurality of first chips are stacked with an offset from each other in a direction parallel to the upper surface of the base substrate, and
a number of chip pads of a first chip of the plurality of first chips that is adjacent to the base substrate is greater than a number of chip pads of a third chip of the first chip group that is on the first chip.

19. The semiconductor package of claim 10, further comprising:
a second molding film extending around the second chip group;
a second redistribution layer on the second molding film;
a third chip group comprising a plurality of third chips on the second redistribution layer; and
a plurality of second outer posts that is electrically connected to the first redistribution layer and the second redistribution layer and extends into the second molding film,
wherein at least one of the plurality of second outer posts at least partially overlaps at least one of the plurality of first outer posts in the first direction and is free from overlap with the second chip group and the third chip group in the first direction.

20. A semiconductor package comprising:
a redistribution substrate;
a plurality of chips that are on the redistribution substrate and are offset from each other in a first direction parallel to an upper surface of the redistribution substrate;
a molding film extending around the plurality of chips;
a redistribution layer on the molding film; and
a plurality of outer posts that are on the redistribution substrate, electrically connected to the redistribution layer, and extend into the molding film,
wherein the redistribution substrate comprises:
a first chip connection pad in a chip area facing the plurality of chips in a direction perpendicular to the upper surface of the redistribution substrate, and electrically connected to a signal pad of a first chip of the plurality of chips;
a second chip connection pad in the chip area, and electrically connected to a thermal pad of the first chip; and
a plurality of outer connection pads electrically connected to the first chip connection pad or the second chip connection pad, and
wherein the plurality of outer posts are on the plurality of outer connection pads.
